(19) United States
(12) Patent Application Publication
(10) Pub. No.: US 2012/0261805 A1
(43) Pub. Date: Oct. 18, 2012

(54) THROUGH PACKAGE VIA STRUCTURES IN PANEL-BASED SILICON SUBSTRATES AND METHODS OF MAKING THE SAME

(75) Inventors: VENKATESH V. SUNDARAM, Alpharetta, GA (US); Fuhan Liu, Atlanta, GA (US); Rao R. Tummala, Greensboro, GA (US); Qiao Chen, Atlanta, GA (US)

(73) Assignee: Georgia Tech Research Corporation, Atlanta, GA (US)

(21) Appl. No.: 13/448,064

(22) Filed: Apr. 16, 2012

Related U.S. Application Data
(60) Provisional application No. 61/475,485, filed on Apr. 14, 2011.

(51) Int. Cl. H01L 23/495; H01L 21/768

(52) U.S. Cl. 257/666; 438/667; 257/E21.597; 257/E23.041

(57) ABSTRACT

The various embodiments of the present invention provide a low cost, low electrical loss, and low stress panel-based silicon interposer with TPVs. The interposer of the present invention has a thickness of about 100 microns to 200 microns and such thickness is achieved without utilizing a carrier and further wherein no grinding, bonding, or debonding methods are utilized, therefore distinguishing the interposer of the present invention from prior art embodiments.

### CROSS-REFERENCE TO RELATED APPLICATION

This application claims the benefit of U.S. Provisional Patent Application Ser. No. 61/475,485, filed 14 Apr. 2011, which is incorporated herein by reference in its entirety as if fully set forth below.

### BACKGROUND

1. Field

The various embodiments of the present invention relate to silicon interposer structures and methods of making the same.

2. Description of Related Art

CMOS-based ICs are beginning to reach performance limits beyond 16 nanometers, and thus the industry focus has begun to change to 3D IC stacking for shortest interconnection length using through-silicon-vias (TSVs). These 3D ICs require 20-50 μm pitch interconnections to package them, as opposed to the current 150 (micron) μm pitch for 2D ICs. Silicon interposers with high density wiring layers and through vias at fine pitch are an attractive alternative to direct chip stacking for 3D integration in side-by-side (2.5D) and stacked (3D) configurations. Silicon interposers are being developed widely around the globe, as organic interposers reach their limits in I/Os, thermal dissipation, mechanical stress and warpage due to the large coefficient of thermal expansion (CTE) mismatch between silicon devices and organic interposers. Most of these developments take advantage of existing and depreciated 200 and 300 mm wafer fabs, using back of end of line (BEOL) tools and processes as well as the newly-developed TSV technology for 3D ICs. Such silicon interposers are limited in performance by high electrical loss of silicon and high cost of wafer-based interposers. Such an approach, therefore, may also be too expensive for many consumer and smart phone electronics. This is due primarily for four reasons: 1) Wafer-based approach results in small number of interposers; some of which may be as large as 30-50 (millimeters) mm, thus driving up the cost of each interposer; 2) BEOL tools and processes are expensive for packaging applications; 3) The TSV process uses DRIE techniques and long cycle time copper plating; and 4) TSVs require insulating liner such as SiO₂ that adds extra cost.

The various embodiments of the present invention addresses the setbacks of the prior art as they provide a silicon interposer that can achieve equivalent interconnect density with significantly higher electrical performance due to low signal loss, at significantly lower cost with the following advances: (1) a panel-based approach that can be scaled to 10× higher in throughput using polycrystalline silicon, a lower cost Si material; (2) silicon core down to 220 microns in thickness without chemical polishing techniques (i.e., grinding); (3) a low cost TPV process without DRIE techniques, SiO₂ liner, and other TSV processes; (4) low elastic modulus polymer liner, for highly reliable TPV at fine pitch; and (5) low cost, double-side process for redistribution layers.

### BRIEF SUMMARY

An exemplary embodiment of the present invention provides a three-dimensional silicon interposer, comprising a silicon substrate in panel or wafer form, wherein the silicon substrate is made from a monocrystalline, polycrystalline, metallurgical grade, or upgraded metallurgical grade materials, and further wherein the silicon substrate is of thickness of less than 300 microns without back grinding; a plurality of through vias defined within the silicon substrate; a polymeric liner lining disposed on first and second sides of the silicon substrate and on the plurality of through vias walls of the substrate; a conductive material deposited within the plurality of through vias using a double sided process; and fine-pitch redistribution layers on first and second sides of the silicon substrate formed simultaneously.

An exemplary embodiment of the present invention provides a three-dimensional silicon interposer based package, comprising a silicon substrate in panel or wafer form, wherein the silicon substrate is made from a monocrystalline, polycrystalline, metallurgical grade, or upgraded metallurgical grade materials; at least one thermal via defined within the silicon substrate having no polymeric liner; and at least one electrical via defined within the silicon substrate having a polymeric liner.

Another exemplary embodiment of the present provides a method of fabricating a three-dimensional silicon interposer, comprising defining a plurality of through vias within a panel-based polycrystalline, metallurgical grade, upgraded metallurgical grade, or combinations thereof silicon substrate; lining each of the through vias with a polymeric liner; filling each of the through vias with a conductive metal; and forming fine-pitch re-distribution layers on first and second sides of the silicon substrate utilizing double side processing methods; wherein no carrier is utilized and further wherein no grinding, bonding, or debonding methods are utilized.

Another exemplary embodiment of the present invention provides a method of fabricating a three-dimensional silicon interposer, comprising defining a plurality of through vias within a monocrystalline wafer silicon substrate; lining each of the through vias with a polymeric liner; filling each of the through vias with a conductive metal; and forming fine-pitch re-distribution layers on first and second sides of the silicon substrate utilizing double side processing methods; wherein no carrier is utilized and further wherein no grinding, bonding, or debonding methods are utilized.

Yet another exemplary embodiment of the present invention provides a method of fabricating a three-dimensional silicon interposer, comprising defining a plurality of through vias within a silicon substrate; lining each of the through vias with a polymeric liner via direct electrophoretic deposition methods without the use of a seed layer; filling each of the through vias with a conductive metal; and forming fine-pitch re-distribution layers on first and second sides of the silicon substrate utilizing double side processing methods; wherein no carrier is utilized and further wherein no grinding, bonding, or debonding methods are utilized.

### BRIEF DESCRIPTION OF THE FIGURES

FIG. 1a illustrates an exemplary embodiment of a silicon interposer in accordance with the present invention.

FIG. 1b illustrates a perspective view of a TPV lined with a polymeric layer and defined within a polycrystalline silicon panel.

FIG. 2 illustrates a prior art method for making a silicon interposer.

FIG. 3 illustrates a method for making a silicon interposer in accordance with the present invention.

FIG. 4 illustrates an alternative method for making a silicon interposer in accordance with the present invention.

FIG. 5 illustrates a method for polymeric formation in accordance with the present invention.

FIG. 6 illustrates another method for polymeric formation in accordance with the present invention.

FIG. 7 illustrates an alternative method for polymeric liner formation in accordance with the present invention.

FIG. 8 illustrates a silicon interposer for LED package devices.

FIG. 9 illustrates a schematic model of a TPV in a silicon interposer.

FIGS. 10a and 10b graphically illustrate electrical simulations of insertion loss and far-end crosstalk plots, respectively, for through vias in CMOS grade and polycrystalline based silicon interposers.

FIGS. 11a and 11b graphically illustrate electrical simulations of insertion loss and far-end crosstalk plots, respectively, for through vias with different sidewall liner thicknesses.

FIGS. 12a and 12b graphically illustrate electrical simulations of insertion loss and far-end crosstalk plots, respectively, for through vias with different diameters.

FIG. 13 illustrates the process flow for through-via fabrication.

FIG. 14 provides top and bottom views of through vias fabricated by three types of lasers.

FIGS. 15a and 15b illustrate cross-sectional views of through-vias drilled in polycrystalline silicon by a UV laser.

FIG. 16 illustrates a cross-sectional view of a polymer filled through-via in silicon.

FIG. 17 illustrates a silicon panel with TPVs and RDLs on both sides.

FIGS. 18-20 graphically illustrate measured insertion loss of shielded CPW signal lines with parametric variations on the number of signal TPVs.

FIG. 21 illustrates an eye diagram plot for a single signal I/O at 3.2 GHz.

FIG. 22 illustrates top and back side views of various embodiments of via diameter and via pitch.

FIG. 23 illustrates a laser ablated inner via successfully fabricated in a polymeric liner.

FIG. 24 illustrates conformal polymer liners in 10-25 μm diameter silicon TPVs.

FIG. 25 illustrates improved alignment accuracy of polymeric liner thickness and via formation.

FIGS. 26a and 26b illustrated cross-sectional views of an electrodeposited polymer liner on the silicon panel.

### DETAILED DESCRIPTION

Referring now to the figures, wherein like reference numerals represent like parts throughout the several views, exemplary embodiments of the present invention will be described in detail. Throughout this description, various components can be identified as having specific values or parameters, however, these items are provided as exemplary embodiments. Indeed, the exemplary embodiments do not limit the various aspects and concepts of the present invention as many comparable parameters, sizes, ranges, and/or values can be implemented.

It should also be noted that, as used in the specification and the appended claims, the singular forms “a,” “an,” and “the” include plural references unless the context clearly dictates otherwise. For example, reference to a component is intended also to include composition of a plurality of components. References to a composition containing “a” constituent is intended to include other constituents in addition to the one named. Also, in describing the preferred embodiments, terminology will be resorted to for the sake of clarity. It is intended that each term contemplates its broadest meaning as understood by those skilled in the art and includes all technical equivalents which operate in a similar manner to accomplish a similar purpose.

Values may be expressed herein as “about” or “approximately” one particular value, this is meant to encompass the one particular value and other values that are relatively close but not exactly equal to the one particular value. By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

It is also to be understood that the mention of one or more method steps does not preclude the presence of additional method steps or intervening method steps between those steps expressly identified. Similarly, it is also to be understood that the mention of one or more components in a composition does not preclude the presence of additional components than those expressly identified.

It shall also be understood that the terms “package,” “structure,” and “interconnect structure” may be used interchangeably and refer to devices that can be used for connecting electronic components across one or more of the generally accepted six levels of interconnect in an electronic system. It shall further be understood that through silicon vias (TSVs) and through package vias (TPVs) may be used interchangeably.

The various embodiments of the present invention provide a low cost, low electrical loss, and low stress panel-based silicon interposer with TPVs. The interposer of the present invention has a thickness of about 100 microns to 200 microns and such thickness is achieved without utilizing a carrier and further wherein no grinding, bonding, or debonding methods are utilized, therefore distinguishing the interposer of the present invention from prior art embodiments.

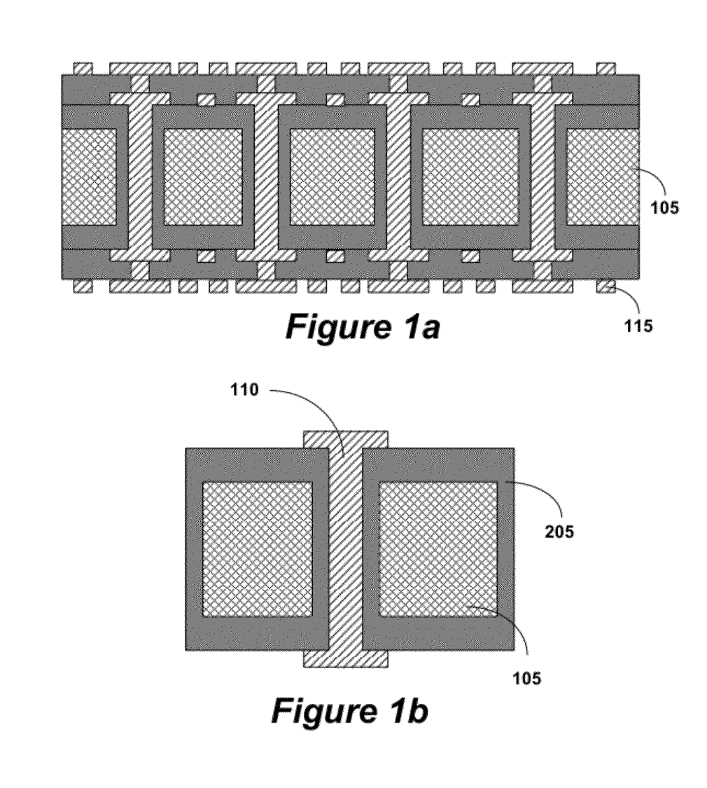

Referring to FIG. 1, there is shown an exemplary embodiment of a silicon interposer 100 in accordance with the present invention. Specifically, there is illustrated a silicon panel or wafer 105. It shall be understood that the term silicon “panel” will be referred to herein, and it encompasses silicon wafers as well. The silicon panel 105 can be made from many materials, for example but not limited to monocrystalline, polycrystalline, metallurgical grade, upgraded metallurgical grade materials, or combinations thereof.

The silicon panel 105 is scalable from a wafer to large panels up to 700 mm×700 mm. Further, the silicon panel 105 can be of a thickness of less than 300 microns, and more specifically of about 100 microns to about 200 microns, which is achieved without any back grinding or polishing steps (as is required in prior art embodiments). It shall be understood that the raw silicon cost is about ten to fifteen times lower than traditional single crystalline silicon wafers of the prior art. Further the lack of back grinding and/or polishing steps substantially reduces manufacturing costs. Thus, the reduction in process steps also lowers the cost of the silicon interposer when compared to prior art embodiments. Such thin silicon panels or wafers are typically fabricated using low cost methods such as directional solidification, electromagnetic casting or czochralski process (CZ). The cast material is then blocked into the final X-Y size as required, and then sliced into thin silicon panels or wafers of the desired thickness in the range of 50-300 um using wire sawing, electrical discharge assisted cutting or other sawing methods, commonly employed in the photovoltaic industry to create raw silicon materials.

A plurality of small-diameter TPVs 110 can be defined within the silicon panel 105. The TPVs 110 can be fabricated by short wavelength laser ablation and the diameters of the TPVs can be as small as 10 microns and as large as 150 microns. It shall be understood that diameters and pitch of the TPVs can be manipulated as desired. The TPVs 110 in the silicon panel 105 can be leveraged to fabricate fine pitch redistribution layers 115 on both sides of the silicon core using simple double side processes such as wet metallization and dry-film polymer dielectric deposition, leading to design flexibility for the double-sided chips at a lower cost than BEOL interposers.

The TPVs 110 can be filled with a conductive metal. The conductive metal can be, for example but not limited to, copper or copper and an additional metal and/or alloy. The additional metal and/or alloy can be selected from a group comprising of tin, tin-silver, tin-copper, tin-silver-copper, or any other metal or alloy with a melting point below about 300° C.

Referring to FIG. 1b, a polymeric liner 205 can be disposed between the silicon panel 105 and TPVs 110 to provide a stress-relief barrier having elastic and insulating properties between the silicon panel 105 and the TPVs 110. It shall be understood that the polymeric liner 205 can be manipulated to a desired thickness. As the polymeric liner 205 thickens, the electrical loss within the silicon interposer is decreased. Thus, in exemplary embodiments, the polymeric liner 205 is thick has a minimum thickness of about 1 micron, and more preferably a thickness of 3 microns. It shall also be understood that, due to the softness of polymeric materials, the silicon interposer 100 has low stress properties. Suitable polymers for the polymeric liner 204 can be, but are not limited to, epoxies such as ABF GX-13 and SU-8, cyanate esters, epoxy blends such as ZIF, hydrocarbons such as RXP4, polyimides such as DuPont ™ Kapton® film, DuPont ™ Pyralux® AC, and DuPont ™ Pyralux® AP, BCB and aromatic polymers, LCP and other long chain polymers. It should be appreciated by those of ordinary skill in the art that the present invention is not limited to these polymers, but can also include other suitable polymers having similar physical and electrical qualities. In exemplary embodiments of the present invention, the polymer is deposited as a dry film, liquid coating or vapor phase deposition thin film. Additionally, it should be understood by those of ordinary skill in the art that the present invention is not limited to polymers, as other non-polymeric materials having similar physical and electrical properties can be used. The stress relief barrier is an elastic interface that helps to maintain the physical connection between the metal conductor that fills the TPVs 110 and the silicon panel, as well as any additional layers such as a metallization seed layer. The elastic property helps to reduce the probability of the occurrence of opens or shorts caused by the metal layer becoming physically detached from the interposer. Additionally, the stress relief barrier can help reduce or eliminate the propagation of cracks in the silicon panel 105 formed either as a manufacturing defect, as a defect introduced during a processing step, or during thermal cycling. One further advantage of certain polymers used as liner is the elimination of the need for a diffusion barrier such as TiN which is typically used for copper metallization on SiO₂ liners due to the diffusion of copper into thin silicon oxide liner and silicon at elevated temperatures and current levels.

Once the silicon interposer 100 is fabricated, and thus complete with the silicon panel 105, TPVs 110, and polymeric liner 205, redistribution layer 115 wiring on both sides of the silicon panel 105 can connect electronic components.

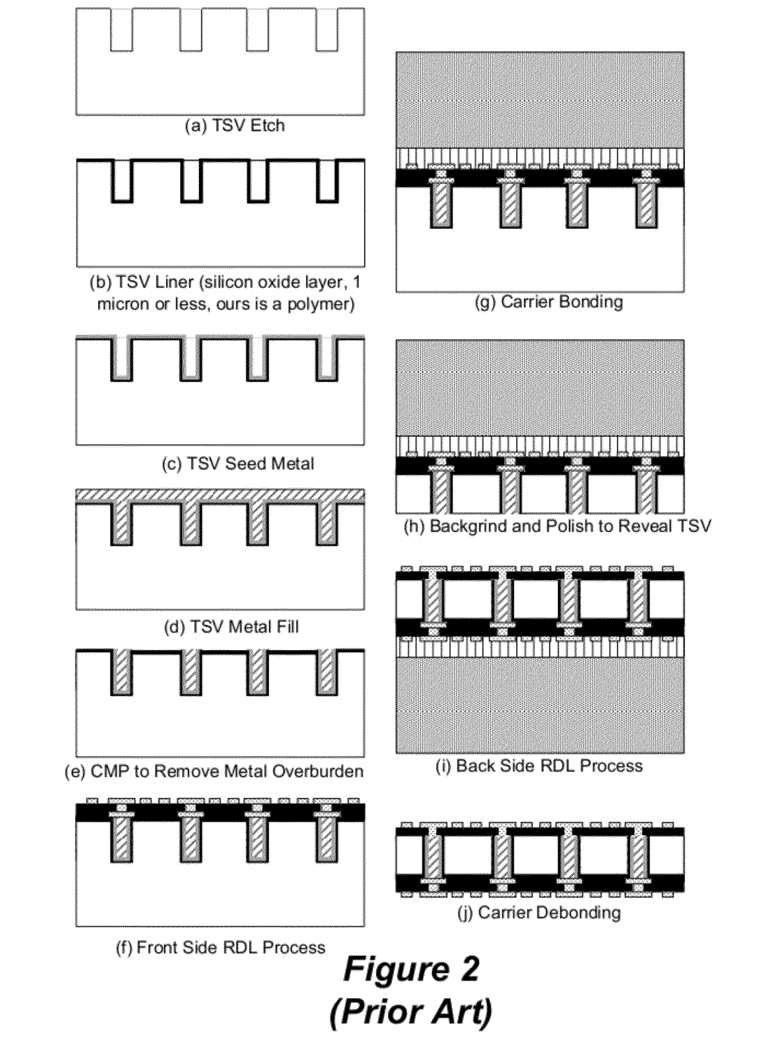

Referring to FIG. 2, there is shown a prior art method of making a silicon interposer. As illustrated in FIG. 2a, a silicon substrate is provided and TSVs are etched within the substrate. A TSV liner, usually silicon oxide having a thickness of 1 micron or less is general disposed within the TSV (FIG. 2b). A metal seed layer is then disposed over the TSV liner (FIG. 2c). The TSV metal is then disposed over the metal seed layer (FIG. 2d), and chemical polishing etching techniques are used to remove any metal overburden (FIG. 2e). A first redistribution layer is then fabricated on a first side (FIG. 2f). A carrier is then bonded to the interposer (FIG. 2g) to support the back grinding and polishing of the silicon substrate to reveal the TSVs (FIG. 2h). A second redistribution layer is then fabricated on a second side (FIG. 2i) and the carrier is removed (FIG. 2j).

The method of the present invention eliminates many of the steps of the prior art, thereby substantially reducing the cost associated with fabrication. For example, there are no grinding, polishing, or carrier steps of the present invention. Further, as mentioned above, the starting silicon panel material substantially minimizes start-up costs.

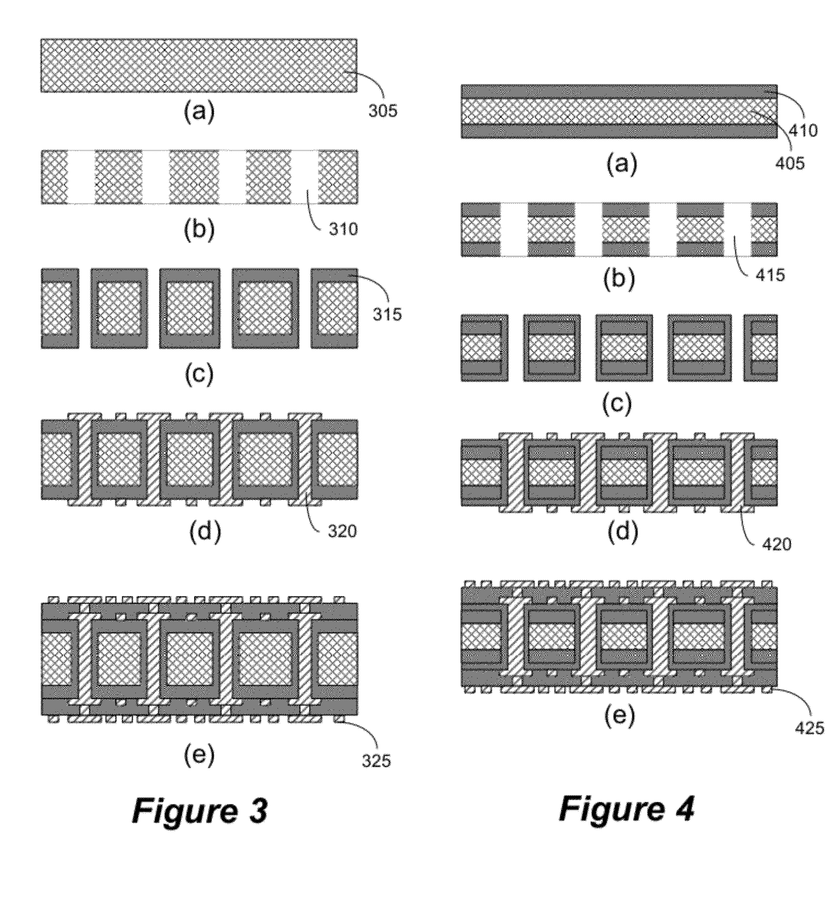

Referring to FIG. 3, there is shown an exemplary method of making the silicon interposer 100 of the present invention. Initially, a thin silicon panel 305 is provided (FIG. 3a). It shall be understood that the silicon panel 305 does not need grinding. TPVs 310 may then be defined within the silicon panel 305 via drilling, etching, or laser ablation methods (FIG. 3b). A polymeric liner 315 may then be disposed within the TPVs 310, such that it simultaneously covers top, bottom, and side wall sides (FIG. 3c). The remaining portions of the TPVs 310 may then be filled with a metal component 320 (FIG. 3d) and redistribution layers 325 may be fabricated on first and second sides of the interposer (FIG. 3e).

Referring to FIG. 4, there is shown yet another exemplary method of making the silicon interposer 100 of the present invention. Initially, a thin silicon panel 405 having polymeric liner disposed on both sides of the silicon panel 405 can be provided (FIG. 4a). TPVs 415 can then be formed using drilling, etching, or laser ablation techniques (FIG. 4b). Another layer of polymeric liner 410 can be disposed within the TPVs 415, to fill the top and bottom sides and coat the side walls (FIG. 4c). The remaining portion of the TPVs 415 may then be filled with a metal component 420 (FIG. 4d) and redistribution layer 425 may be fabricated on first and second sides of the interposer (FIG. 4e).

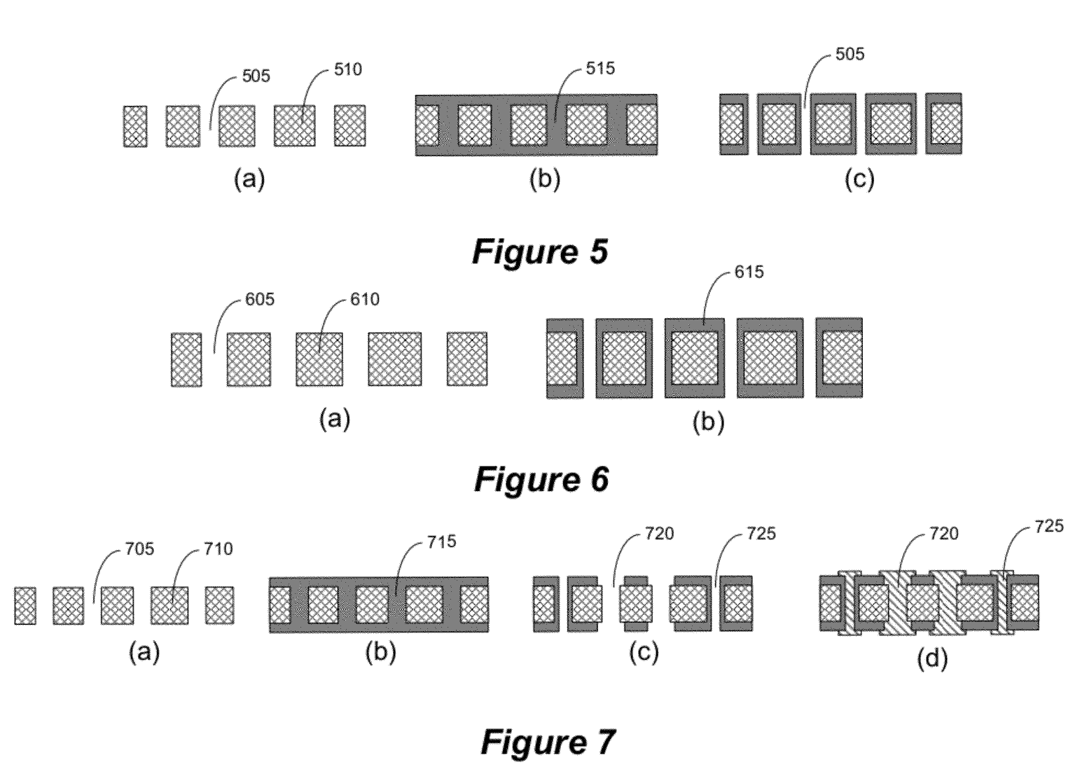

Referring to FIG. 5, there is shown a method for polymeric liner formation. As illustrated in FIG. 5a, a plurality of TPVs 505 can be defined within the silicon panel 510 via laser ablation techniques. As illustrated in FIG. 5b, a polymeric liner 515 may be disposed on top and bottom sides and within the TPVs 505 via lamination techniques. Inner TPVs 505 may then be defined within the polymeric liner 515, as illustrated in FIG. 5c. This method enables the polymeric liner 515 and the TPVs 505 to be manipulated to a desired thickness. Further, this method is preferred for thicker polymeric liners (for example, 50 microns in thickness) and larger diameter TPVs (for example, up to 150 microns). The remaining portions of the TPVs 505 can be filled with a metal material, for example, copper.

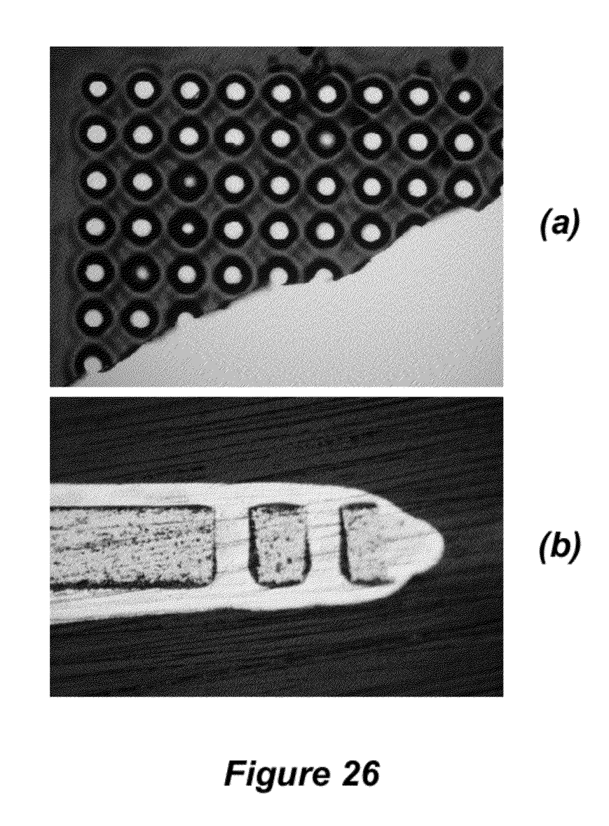

Referring to FIG. 6, there is shown an alternative method for polymeric liner formation. As illustrated in FIG. 6a, a plurality of TPVs 605 can be defined within the silicon panel 610 via laser ablation techniques. As illustrated in FIG. 6b, a conformal polymer liner 615 may be deposited by spray coating, chemical vapor deposition, or electrophoresis techniques. This technique allows for the simultaneous formation of polymeric liner 615 on the top and bottom sides and sidewalls of the TPVs 605. It shall be understood that unlike in the prior art, where a metal seed layer is required before depositing the polymeric liner, this method does not require a metal seed layer as the polymeric liner 615 can be directly deposited on the silicon panel 610 utilizing the deposition techniques described above. FIGS. 26a and 26b illustrated cross-sectional views of an electrodeposited polymer liner on the silicon panel. This method is preferred for smaller parameters, such as thinner polymeric layers (for example, 1 micron) and smaller diameter TPVs (for example, 10 microns). The remaining portions of the TPVs 605 can be filled with a metal material, for example, copper.

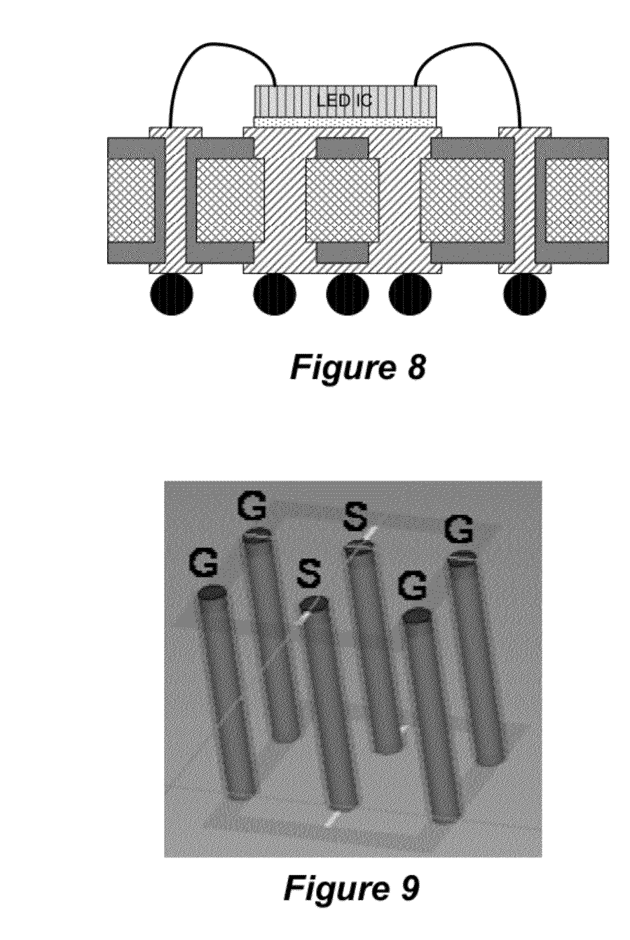

Referring to FIG. 7, there is shown yet an alternative method for polymeric liner formation. As illustrated in FIG. 7a, a plurality of TPVs 705 can be defined within the silicon panel 710 via laser ablation techniques. The polymer liner 715 can be disposed within the TPVs 705 via lamination techniques, as illustrated in FIG. 7b. As illustrated in FIG. 7c, laser drilling techniques can be used to manipulate the thickness of the polymeric liner 715 (and thus manipulate the diameter of the TPVs) to formulate thermal vias 720 (i.e., polymeric liner being 0 microns in thickness) and electrical vias 725 (i.e., polymeric liner having a thickness greater than 0 microns) within the same silicon interposer. Laser drilling techniques allows certain vias to be overfilled (to form an electrical via 725) with polymeric liner 715 and certain vias to be underfilled with polymeric liner 715 (to form a thermal via 720). Such a method is desirable for the fabrication of silicon interposers for devices, such as but not limited to, LED device packages, as illustrated in FIG. 8.

### EXAMPLES

The various embodiments of the present invention are illustrated by the following non-limiting examples.

### Example #1

### Electrical Modeling of TPVs/TSVs

Electromagnetic modeling and simulation results were presented to compare the electrical performance of through silicon vias (TSVs) and TPVs in polycrystalline-silicon interposers. Parametric studies of the TPV diameter and sidewall liner thickness on electrical performance is also presented.

TPVs were modeled and simulated for their electrical characteristics by means of 3D full-wave Electromagnetic (EM) simulations. CST Microwave StudioTM (CST-MWS) was used as a 3D full-wave EM simulator to study the system response of the vias up to 10 GHz. The via model is shown in FIG. 9. The model comprises two signal vias (marked as ‘S’ in FIG. 9) surrounded by four ground vias (marked as ‘G’ in FIG. 9). The vias were excited with discrete (lumped) ports on their top and bottom surfaces.

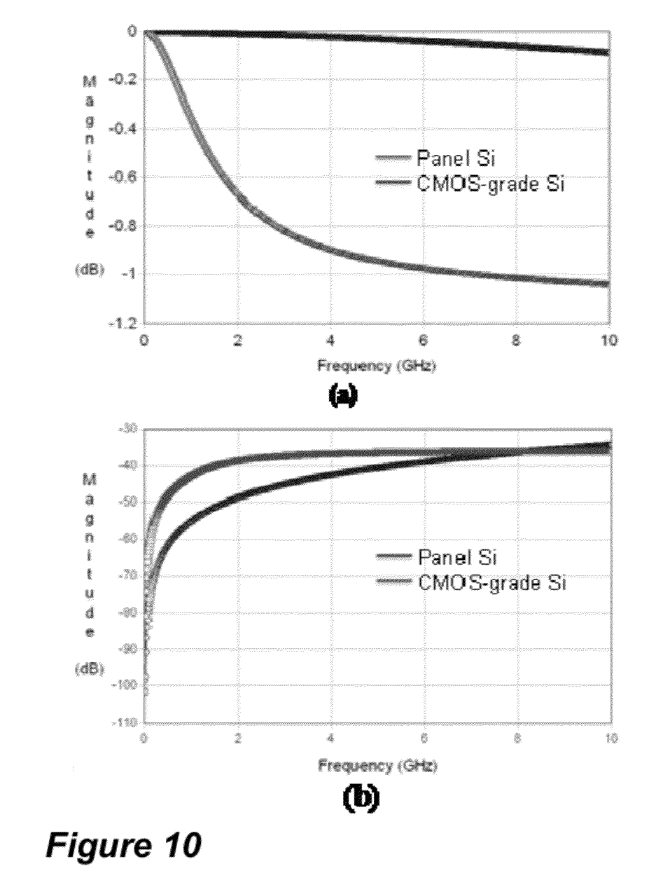

An electrical simulation of insertion loss and crosstalk between the vias in two types of Si interposers is compared in FIGS. 10a and 10b. TPVs in polycrystalline Si (0.15 Ω-cm resistivity) is compared with TSVs in wafer-based CMOS grade Si (10 Ω-cm resistivity). The thickness of the Si substrate was about 220 μm. The diameter and pitch of these Cu filled vias were about 30 μm and about 120 μm, respectively. The TSVs were modeled with about 1 μm thick sidewall SiO₂ liner, while the TPVs were modeled with about 5 μm thick sidewall polymer liner.

It is observed from FIGS. 10a and 10b that the TPVs in polycrystalline Si have lower loss (until about 10 GHz) and lower crosstalk (until about 7 GHz) as compared to the TSVs in CMOS grade Si. The better electrical behavior of the TPVs can be attributed to the thicker polymer lined sidewall and surface liner in these interposers. This helps reduce the substrate loss and coupling in the Si substrate.

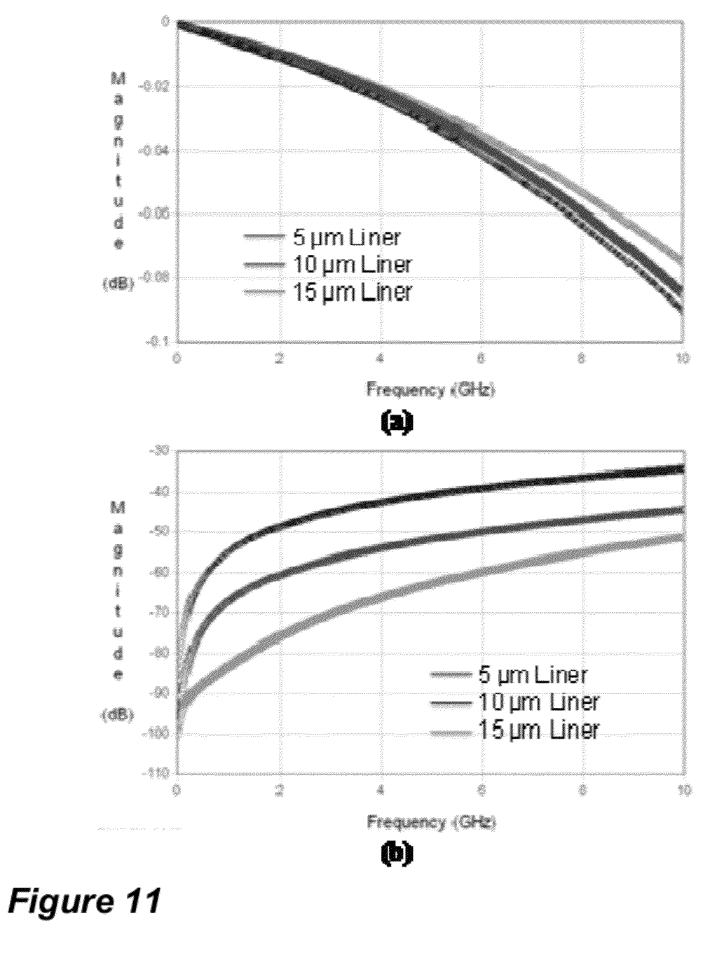

The effect of the sidewall liner thickness on the insertion loss and crosstalk in TPVs is simulated in FIGS. 11a and 11b. The TPV diameter and pitch was about 30 μm (diameter of the Cu filled region) and about 120 μm, respectively. The Si substrate resistivity and thickness was about 0.15 Ω-cm and about 220 μm respectively. It is seen from FIGS. 11a and 11b that the insertion loss and crosstalk can be reduced by using a thicker sidewall polymer liner.

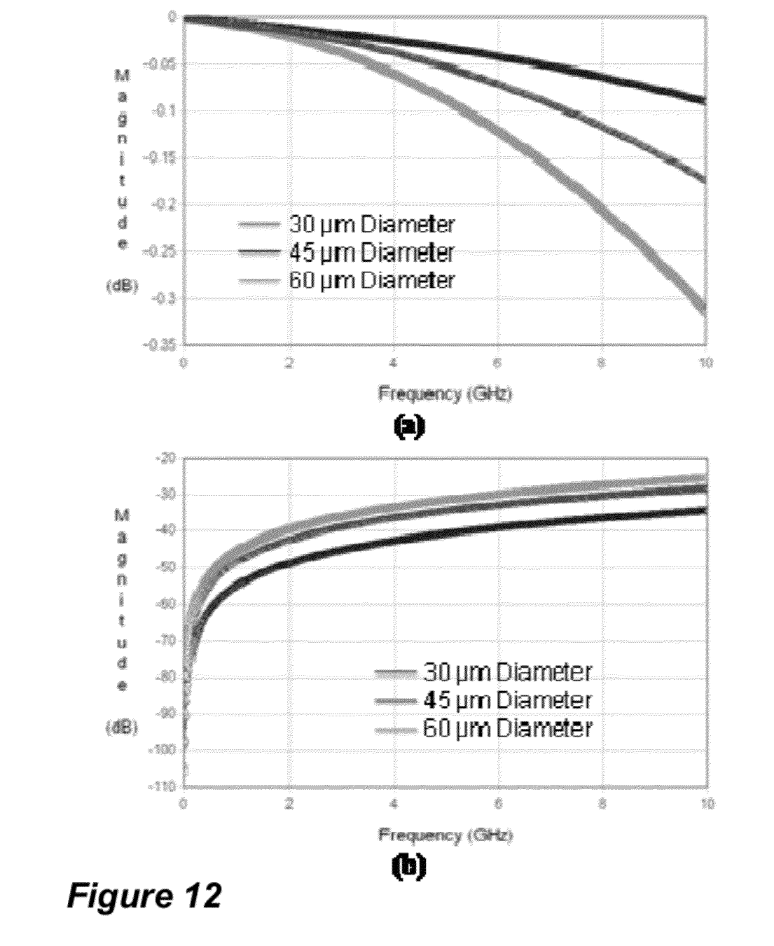

A simulation of the effect of via diameter on its loss and crosstalk is studied in FIGS. 12a and 12b. The vias were modeled in about 220 μm thick polycrystalline Si (0.15 Ω-cm resistivity) with about 5 μm thick polymer sidewall liner. The TPV pitch was about 120 μm. The loss in the TPVs can be reduced by decreasing via diameter. Smaller TPVs have smaller sidewall capacitance (due to smaller diameter) and smaller substrate conductance (due to larger spacing between the TPVs). This helps in reducing the loss. Due to the greater spacing between the smaller TPVs, their crosstalk is lower as compared to the larger TPVs.

The performance of TPVs in polycrystalline Si (with thick polymer liner) is better as compared to that of wafer-based CMOS grade Si with thin SiO₂ liner. The electrical performance of the TPVs can be improved by decreasing its diameter and by increasing the sidewall liner thickness.

### Example #2

### Mechanical Design of TPVs/TSVs

Finite Element (FE) modeling was performed using Ansys to compare the proposed TPV structure with a polymer liner to the current 3D IC structure with TSV structure with thin SiO2 liner in terms of interfacial shear stresses (σ_{xy}) due to thermal loading. The effect of geometry (liner thickness and via diameter) on the axial stress (σₓ) of a polymer liner in TPV structure was also studied.

The material properties used in the simulations are given in Table 1. A standard thermal load cycle of −55 to 125° C. was used for the analysis.

TABLE 1

| | Young's | | CTE | Stress free |
|---|---|---|---|---|
| | Modulus (GPA) | Poisson's Ratio | (ppm/° C.) | Temp. (° C.) |
| Silicon | 185 | 0.28 | 2.6 | 25 |
| Polymer | 6.9 | 0.3 | 31 | 120 |
| Copper | 121 | 0.3 | 17.3 | 25 |
| SiO₂ | 70 | 0.3 | 0.5 | 25 |

The interfacial shear stress localization occurs at the Cu-Polymer (about −90 MPa) and Polymer-Si (about 72 MPa) junctions in the case of TPV structures, and at Cu-SiO₂ (about 124 MPa) junctions in the case of TSV structures. The relatively higher interfacial shear stress localization in TSV structures can be attributed to the higher CTE mismatch of SiO₂ with Cu vias. This makes the standard Si interposers more susceptible to delamination failures compared to TPV structures fabricated with polymer liners. Due to higher stiffness of SiO₂, the TSV structures are more prone to cohesive cracks compared to TPV structures. It is also expected that TSV structures would experience higher stress during the back grinding process required for fabricating these structures.

### Example #3

### TPV Fabrication Process

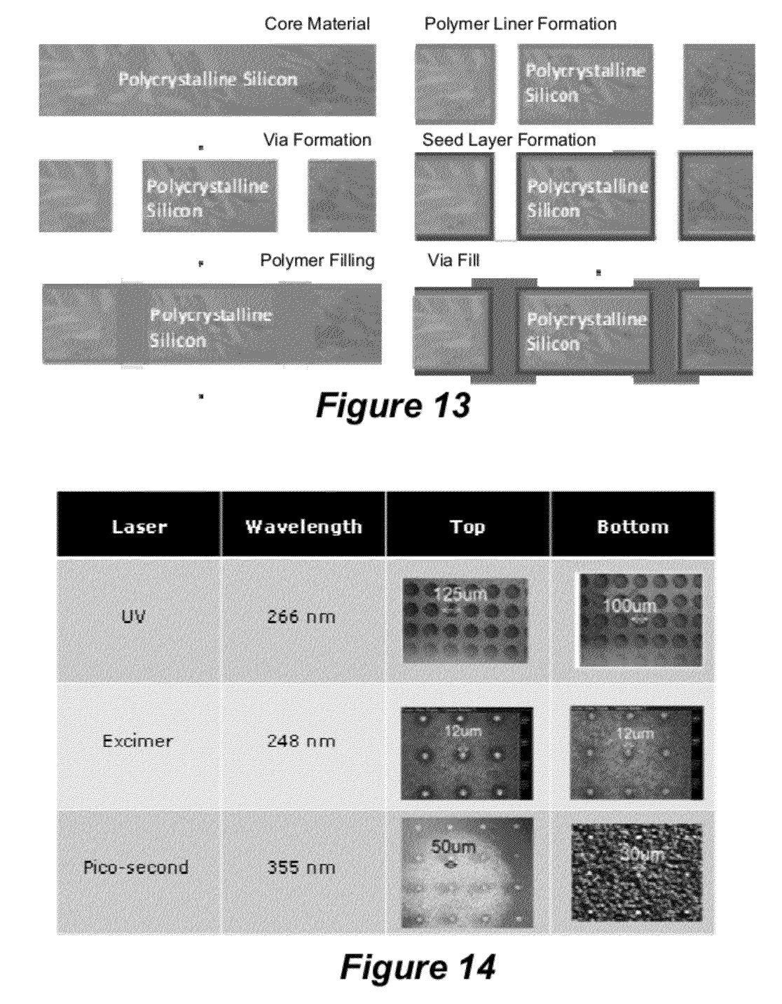

FIG. 13 illustrates the process flow used to fabricate the TPV in a polycrystalline silicon panel.

### Example #4

### TPV Formation

Several methods for TPV formation in polycrystalline silicon were explored as the traditional DRIE processes are too slow to drill TPVs in silicon interposers of about 220 μm thick polycrystalline silicon. To solve this problem, TPV formation by laser ablation (UV, excimer and pico-second lasers) was studied. Top and bottom views of the vias fabricated by three types of lasers are compared in FIG. 14 (refer to alternative embodiments in FIG. 22).

The UV laser with a wavelength of about 266 nm was faster but resulted in large via entrance diameters ranging from about 75-125 μm. The via exit diameter (ranging from about 50-100 μm) was smaller than the entrance diameter, indicating significant via taper. The excimer laser was able to drill smaller vias (about 10-20 μm diameter) than the UV laser. The excimer laser was able to form nearly vertical TPV sidewall without micro-cracking due to minimal thermal damage to the silicon material. Excimer laser processing can be scaled to higher throughput by parallel mask projection ablation. Picosecond lasers can further reduce the heat generated during the laser ablation process. TPVs with about 10-50 μm diameter were formed by pico-second laser. However, this method is currently limited by slow processing speed and serial via formation process.

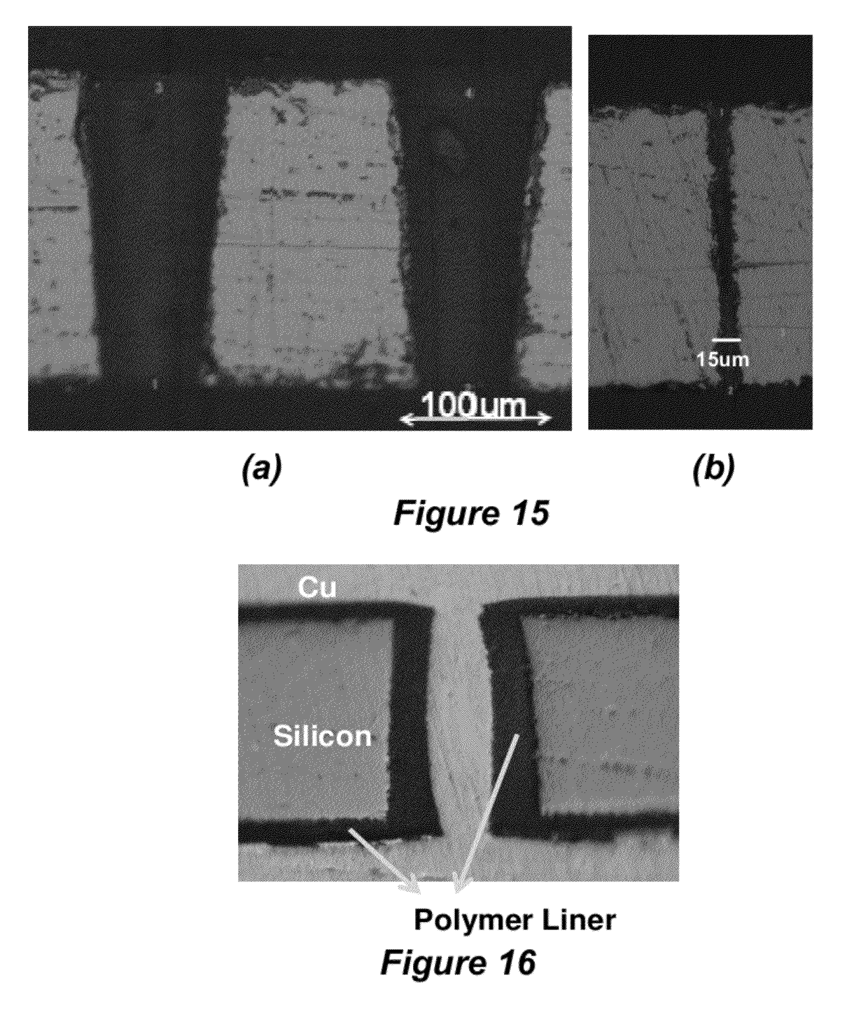

For this initial study, short wavelength UV lasers were chosen for TPV formation in polycrystalline silicon. FIGS. 15a and 15b show a typical cross section picture of a laser ablated through-via in polycrystalline silicon, wherein FIG. 15a illustrates a large via, whereas FIG. 15b illustrates a smaller, more conformal via.

### Example #5

### Polymer Filling and Liner Formation

A novel polymer liner approach is presented to replace the current combination of SiO₂ and diffusion barriers used in the processing of CMOS-based silicon interposers. The technical approach involves polymer filling of TPV, followed by laser ablation to form an “inner” via resulting in a via side wall liner of controlled thickness.

The laser drilled silicon samples were first cleaned using a plasma treatment. About 30 μm thick polymer film was laminated to cover the surface and fill the TPVs. This was done by an optimized double-side lamination process with hot press, resulting in void-free filling without cracking the silicon. FIG. 16 shows the optical cross-sectional image of polymer laminated silicon substrate with polymer-filled TPV (about 125 μm and about 100 μm via entrance and exit diameter respectively). Adhesion between polymer and silicon was checked by initial tape test for peel strength and the samples showed good adhesion.

UV laser ablation was used to drill through holes in the polymer filled vias. The inner via diameter was controlled to ensure proper sidewall polymer liner thickness.

### Example #6

### TPV Metallization

The TPV metallization consisted of two steps: 1) Cu seed layer formation, and 2) Cu electroplating. Electroless plating, a fast, low cost process, was used in this study to form an about 0.5-1 μm thick copper seed layer for further electroplating. The polycrystalline silicon sample with via in polymer was first cleaned using plasma to remove any impurities on the surface. After rinsing the sample, Cu was plated by electroless deposition on the top and bottom surfaces of the sample, and along the via side wall. A fast, void-free electroplating was performed to fill the vias with Cu. Alternate filling methods to improve the throughput of the via metallization are under investigation.

### Example #7

### Electrical Design of Low-Loss Silicon Interposer

Electromagnetic modeling was performed to analyze the electrical performance of Si TPVs in panel-silicon interposers. The impact of wirelength and number of TPVs on the signal path on the electrical performance was studied using parametric analysis. TPVs were modeled and simulated for their electrical characteristics by means of 3D full-wave Electromagnetic (EM) simulations. CST Microwave Studio was used as a 3D full-wave EM simulator to study the system response of the vias up to 20 GHz. The vias were excited with discrete (lumped) ports on their top and bottom surfaces and frequency-domain simulations were carried out for the CPW signal lines. Scattering parameters were used as a metric to study signal performance and BW.

### Example #8

### Test Vehicle of Low-Loss Silicon Interposer

Two-metal layer test vehicles containing co-planar lines (CPW) with TPV transitions were designed and fabricated to form 3D Si Interposers. The resistivity and thickness of the Si substrate was 0.15 Ω-cm and 220 μm respectively, with a surface polymer liner thickness of 40 μm. The inner TPV diameter (copper-filled) was 60 μm, while the outer TPV diameter (in silicon) was 150 μm, resulting in a polymer liner thickness of 55 μm. The design rules used in this test vehicle are summarized in Table 2.

TABLE 2

| Parameter | Dimensions | |
|---|---|---|
| Silicon Resistivity | 0.15Ω-cm | |
| Substrate Thickness | 220 | μm |
| Polymer Film Thickness | 40 | μm |
| TPV Inner Diameter | 50-60 | μm |
| TPV Outer Diameter | 150-170 | μm |

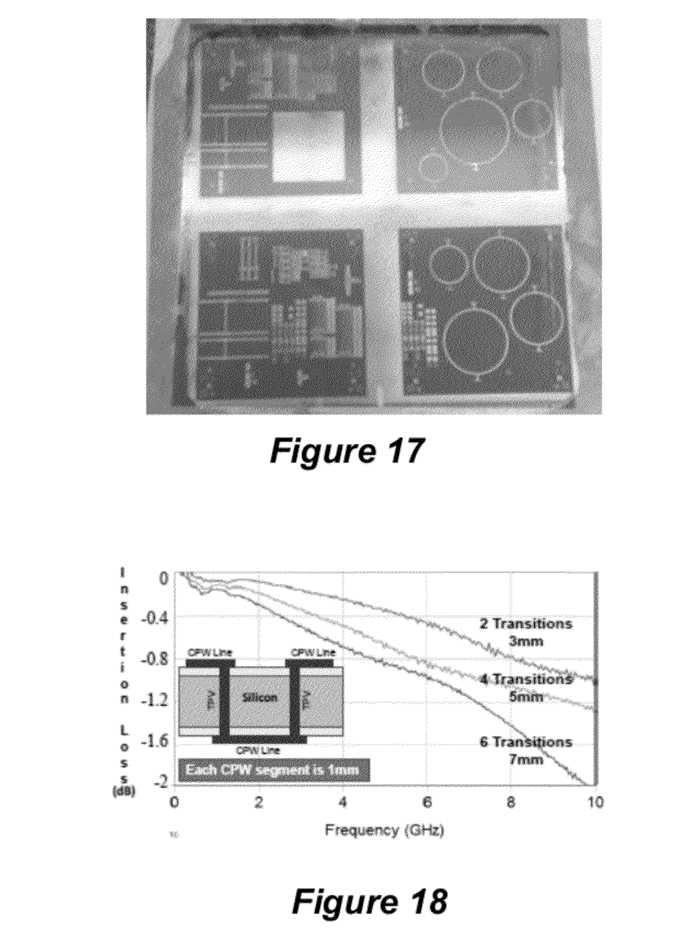

Co-planar waveguide transmission lines with parametric variations in length and routing were fabricated along with other electrical structures. The fabricated CPW lines were 160 μm wide. The gap between the signal and ground was 36.5 μm. VNA measurements were performed after SOLT calibrations and the CPW lines were characterized till 20 GHz. Insertion loss performances between different traces were compared at a target frequency of 2.4 GHz. The completed 156 mm×156 mm silicon panel with TPVs and RDL on both sides is shown in FIG. 17.

### Example #9

### Variation in TPV Transitions of Low-Loss Silicon Interposer

FIG. 18 presents the measured insertion loss of shielded CPW signal lines with parametric variations on the number of signal TPVs. The CPW traces were designed on both metal layers with multiple TPV transitions to route them. It was seen that the insertion loss component increased with an increase in the number of transitions and the rate of insertion loss increased with the rise in frequency. However, the overall loss remained below <0.3 dB at 2.4 GHz, demonstrating good signal quality even with multiple routing TPVs on the signal line. Thus, the interposer can be used to route multiple signal layers with low insertion loss.

### Example #10

### Variation in Signal Length of Low-Loss Silicon Interposer

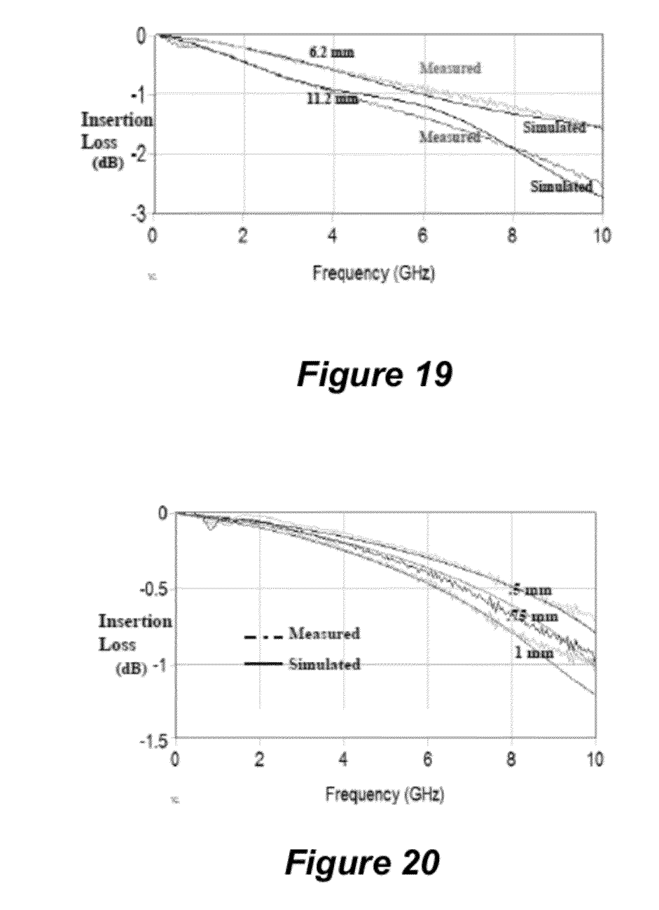

The performance impact due to an increase in a signal path, with and without signal TPVs was analyzed. The simulated results from 3D EM solvers were compared with the measured results and a good model to hardware correlation was observed. These results are presented in FIGS. 19 and 20 respectively. First, CPW traces were designed on a single metal layer without TPV transitions. It was seen that the insertion loss component increased with an increase in signal length. For a signal length of 6.2 mm, the insertion loss was observed to be 0.35 dB at 2.4 GHz. Thus, long lines can be routed on the proposed silicon interposer with low loss comparable to organic substrates with ultra-small design features. However, longer traces followed the trend of increasing the insertion loss rapidly. Thus, increased length of CPW trace length decreases the overall signal quality. In the second scenario as seen in the schematic in FIG. 19, the CPW traces containing TPVs were routed on both the metal layers. Parametric variations with 0.5 mm length increase were designed. The insertion loss increased with each variation in signal length as shown in FIG. 20. However, the overall impact of small wire length increase on the insertion loss at lower frequencies was negligible. Thus, local routing can be performed on the interposer between signal TPVs without significant impact on the signal quality.

### Example #11

### High Bandwidth Logic-To-Memory 3D Interposer with Polycrystalline Silicon

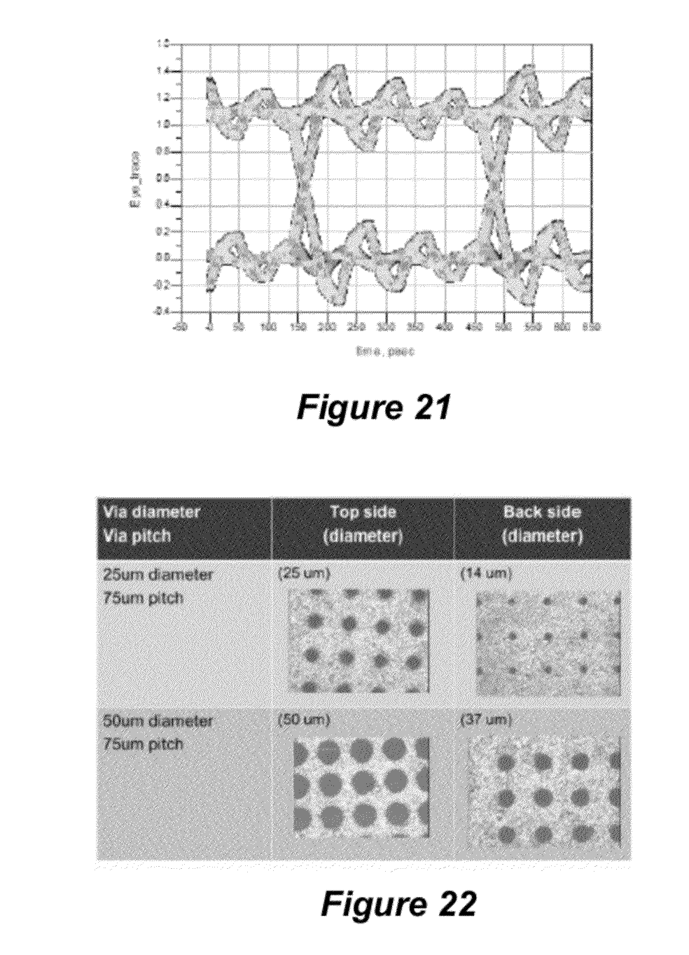

Eye diagram plots were generated from the measured S-parameter data on CPW lines with signal TPVs. The rise and fall time were calculated based on 25% switching time. FIG. 21 presents an eye diagram plot for a single signal I/O at 3.2 GHz. The rise and fall time was set at 80 ps, with a 128 PRBS input. Single ended signaling scheme was used without equalization. Thus, data transmission is observed with BW of 3.2 Gbps/pin, demonstrating high signal quality.

### Example #12

### TPV and Liner Process Advances

In previous studies, the process flow of fabricating a low cost panel-based polycrystalline silicon interposer prototype with polymer liner was demonstrated. The TPV and polymer liner formation involved the laser ablation of an outer via in the silicon substrate and polymer filling in this outer via, followed by laser ablation of the polymer to fabricate inner via.

However, much finer via pitch is required to achieve high bandwidth interconnection. Short wavelength UV laser ablation was used to reduce the outer and inner via diameters in a new series of polycrystalline silicon material with a slightly reduced thickness of 200 μm and a sheet resistivity of 0.5-0.6 Ω-cm. This process was selected from among several laser options reported earlier, because of its fast process speed and feasibility of fabricating small outer via diameters in the polycrystalline silicon panel. As shown in FIG. 22, small via diameters from 25 μm to 50 μm with a via pitch of 75 μm were achieved (refer to FIG. 14 for alternative embodiments). Fabricated vias had a slight taper with the exit side via diameter smaller than the entrance side by approximately 10˜15 μm for a silicon thickness of 200 μm.

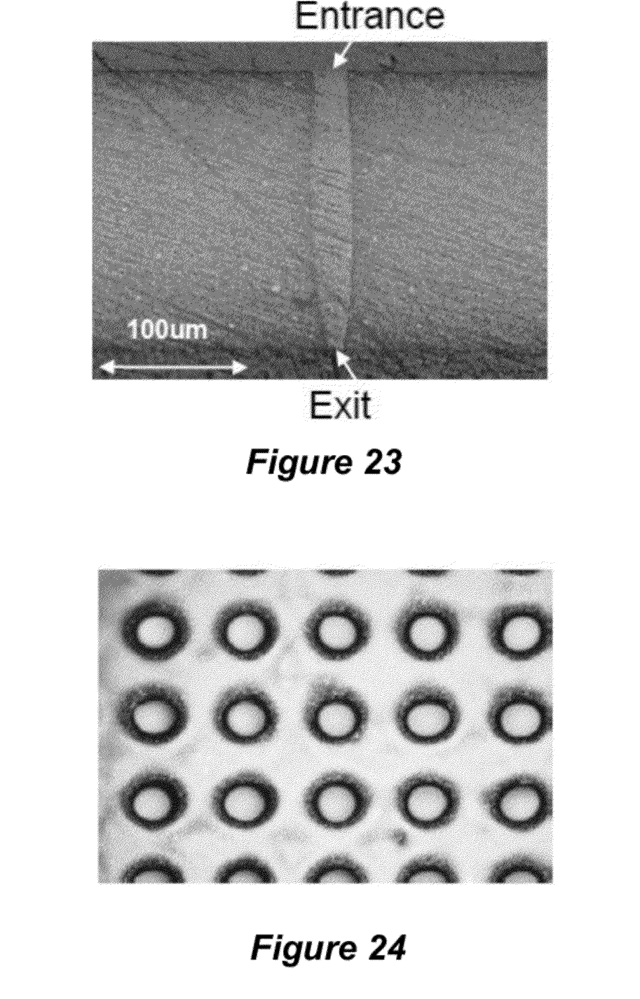

Polymer filling without voiding in these small vias was achieved using a standard double sided vacuum lamination process with appropriate build-up polymer material. In this fabrication method, the difference in diameter of the outer and inner via defines the thickness of the polymer liner and a thick liner helps to reduce the loss of the TPV in silicon. Therefore, in order to control liner thickness at fine via pitch, miniaturization of inner via diameter is critical. The feasibility of fabricating small inner vias in the polymer fill was assessed using UV laser ablation. Since it is only the polymer component which is ablated during the inner via formation, a 240 μm thick polymer film sample was prepared and UV laser ablation was used to form small diameter through vias in the polymer to emulate the inner via requirement. By optimizing the laser parameters, an inner via as small as 35 μm diameter was successfully fabricated in the polymer as shown in FIG. 23.

The final challenge in achieving small via diameter and pitch with the double laser ablation process was the alignment accuracy of the outer and inner via steps. In the present study, a minimum difference in the outer and inner via diameters of 30 μm was necessary to account for alignment tolerance. A new test vehicle for electrical characterization was fabricated using a design rule of 100 μm outer via diameter in silicon and 50 inner via diameter in the polymer fill targeting a minimum liner thickness of 10-15 μm.

Alternate processes to form conformal polymer liners in 10-25 μm diameter silicon TPVs are being explored and initial feasibility of liner thickness of 3-5 μm on the via walls and surface with complete coverage has been demonstrated as shown in FIG. 24.

### Example #13

### Impact of Liner Thickness Variation on Finer Pitch TPV Performance

Initial characterization on the finer pitch TPV structures showed major impact of liner thickness variation on the signal performance. This misalignment resulted in the polymer TPV liner thickness to decrease on one side of the via, creating a leakage path between the copper and the silicon substrate. As a result, a significant increase in insertion loss was observed. This increase was much higher at lower frequencies, and this electrical behavior can be used to determine and analyze the presence of a TPV failure.

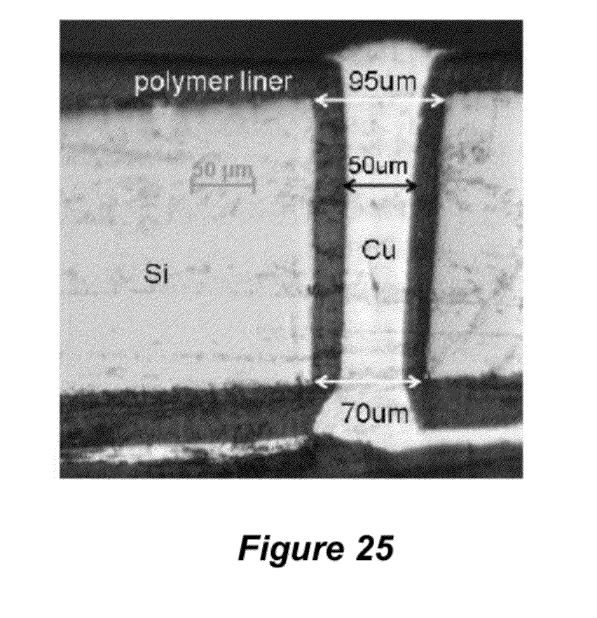

The laser process was optimized by including additional alignment targets for the second laser ablation, and improved alignment accuracy was achieved as seen in FIG. 25.

The outer via diameter was 95 μm at the entrance and 70 μm at the exit side while inner via diameter was 50 μm and precisely centered inside the via. Finer TPV pitch of 120 μm has been recently demonstrated compared to the 250-300 μm pitch TPV reported last year. Thickness of the polymer liner inside the via was around 20 μm in this case and can be increased by further reducing the inner via diameter. The electrical characterization of the finer pitch TPVs in polycrystalline silicon interposer will be reported in the future.

While the present disclosure has been described in connection with a plurality of exemplary aspects, as illustrated in the various figures and discussed above, it is understood that other similar aspects can be used or modifications and additions can be made to the described aspects for performing the same function of the present disclosure without deviating therefrom. For example, in various aspects of the disclosure, methods and compositions were described according to aspects of the presently disclosed subject matter. However, other equivalent methods or composition to these described aspects are also contemplated by the teachings herein. Therefore, the present disclosure should not be limited to any single aspect, but rather construed in breadth and scope in accordance with the appended claims.

We claim:

1. A three-dimensional silicon interposer, comprising:
a silicon substrate in panel or wafer form, wherein the silicon substrate is made from a monocrystalline, polycrystalline, metallurgical grade, or upgraded metallurgical grade materials, and further wherein the silicon substrate is of thickness of less than 300 microns without back grinding;
a plurality of through vias defined within the silicon substrate;
a polymeric liner lining disposed on first and second sides of the silicon substrate and on the plurality of through vias walls of the substrate;
a conductive material deposited within the plurality of through vias using a double sided process; and
fine-pitch redistribution layers on first and second sides of the silicon substrate formed simultaneously.

2. The silicon interposer of claim 1, wherein the interposer has a thickness of about 100 microns to about 200 microns.

3. The silicon interposer of claim 1, wherein the silicon substrate is in panel form up to about 700 mm×700 mm.

4. The silicon interposer of claim 1, wherein the through vias have a diameter of about 10 microns to about 150 microns.

5. The silicon interposer of claim 1, wherein the polymeric liner is at least about 1 micron in thickness.

6. A three-dimensional silicon interposer based package, comprising:
a silicon substrate in panel or wafer form, wherein the silicon substrate is made from a monocrystalline, polycrystalline, metallurgical grade, or upgraded metallurgical grade materials;
at least one thermal via defined within the silicon substrate having no polymeric liner; and
at least one electrical via defined within the silicon substrate having a polymeric liner.

7. A method of fabricating a three-dimensional silicon interposer, comprising:
defining a plurality of through vias within a panel-based polycrystalline, metallurgical grade, upgraded metallurgical grade, or combinations thereof silicon substrate;
lining each of the through vias with a polymeric liner;
filling each of the through vias with a conductive metal; and
forming fine-pitch re-distribution layers on first and second sides of the silicon substrate utilizing double side processing methods;
wherein no carrier is utilized and further wherein no grinding, bonding, or debonding methods are utilized.

8. The method of claim 7, wherein the plurality of through vias are defined utilizing laser ablation techniques.

9. The method of claim 7, wherein a conformal polymeric liner is deposited on the silicon substrate to fill the through vias utilizing spray coating, chemical vapor deposition techniques, or electrophoresis.

10. The method of claim 9, wherein no metal seed layer is used.

11. The method of claim 9, wherein the polymeric liner has a minimum thickness of 1 micron.

12. The method of claim 9, wherein the through vias have a minimum diameter of 1 micron.

13. The method of claim 7, wherein the polymeric layer is deposited utilizing lamination techniques.

14. The method of claim 13, wherein the polymeric liner is about 50 microns in thickness.

15. The method of claim 13, wherein the through vias has a diameter of about 150 microns.

16. The method of claim 7, wherein a selective polymeric layer is deposited to form at least one thermal through via and at least one electrical through via.

17. A method of fabricating a three-dimensional silicon interposer, comprising:
defining a plurality of through vias within a monocrystalline wafer silicon substrate;
lining each of the through vias with a polymeric liner;
filling each of the through vias with a conductive metal; and
forming fine-pitch re-distribution layers on first and second sides of the silicon substrate utilizing double side processing methods;
wherein no carrier is utilized and further wherein no grinding, bonding, or debonding methods are utilized.

18. The method of claim 17, wherein the plurality of through vias are defined utilizing laser ablation techniques, plasma etching, or drilling methods.

19. The method of claim 17, wherein a conformal polymeric liner is deposited on the silicon substrate to fill the through vias utilizing spray coating, chemical vapor deposition techniques, or electrophoresis.

20. The method of claim 19, wherein no metal seed layer is used.

21. The method of claim 19, wherein the polymeric liner has a minimum thickness of 1 micron.

22. The method of claim 19, wherein the through vias have a minimum diameter of 1 micron.

23. The method of claim 17, wherein the polymeric layer is deposited utilizing lamination techniques.

24. The method of claim 23, wherein the polymeric liner is about 50 microns in thickness.

25. The method of claim 23, wherein the through vias has a diameter of about 150 microns.

26. The method of claim 17, wherein a selective polymeric layer is deposited to form at least one thermal through via and at least one electrical through via.

27. A method of fabricating a three-dimensional silicon interposer, comprising:
defining a plurality of through vias within a silicon substrate;
lining each of the through vias with a polymeric liner via direct electrophoretic deposition methods without the use of a seed layer;
filling each of the through vias with a conductive metal; and
forming fine-pitch re-distribution layers on first and second sides of the silicon substrate utilizing double side processing methods;
wherein no carrier is utilized and further wherein no grinding, bonding, or debonding methods are utilized.

28. The method of claim 27, wherein the silicon substrate is a silicon panel made from polycrystalline, metallurgical grade, or upgraded metallurgical grade materials, or combinations thereof.

29. The method of claim 27, wherein the silicon substrate is a silicon wafer made from monocrystalline materials.
